(19) United States
(12) Patent Application Publication
(10) Pub. No.: US 2004/0130401 A1
(43) Pub. Date: Jul. 8, 2004

(54) Signal generator capable of varying frequency of an output signal over a wide range

(75) Inventor: Yasuhiro Ikarashi, Fukushima-ken (JP)

Correspondence Address: Brinks Hofer Gilson & Lione, P.O. Box 10395, Chicago, IL, 60610, US

(73) Assignee: Alps Electric Co, Ltd.

(21) Appl. No.: 10/736,924

(22) Filed: Dec. 15, 2003

(30) Foreign Application Priority Data
Dec. 17, 2002 (JP) 2002-007972

(51) Int. Cl. H03B 1/00

(52) U.S. Cl. 331/74

(57) ABSTRACT

A signal generator according to the present invention includes a voltage controlled oscillation circuit and frequency divider circuits for frequency-dividing an oscillation signal output from the voltage controlled oscillation circuit. The signal generator also includes a control voltage input terminal and frequency division signal output terminals. The control voltage input terminal inputs an external control voltage for determining the frequency of the oscillation signal. The frequency division signal output terminals output frequency division signals output from the corresponding frequency divider circuits.

This application claims the benefit of Japanese Patent, Application No.:2002-007972, filed on Dec. 17, 2002, which is incorporated herein by reference.

### BACKGROUND OF THE INVENTION

1. Field of the Invention

The present invention relates to signal generators used for transmitting and receiving circuits in portable telephones or the like.

2. Description of the Related Art

A known signal generator is described with reference to FIGS. 5 and 6. FIG. 5 shows a circuit structure of a voltage-controlled oscillator functioning as a signal generator. FIG. 6 is an exploded perspective view of the known signal generator.

Referring to FIG. 5, an external power supply voltage is applied between a power terminal 31 and a ground terminal 32. The collector of an oscillating transistor 33 is connected to the power terminal 31, and the emitter of the oscillating transistor 33 is connected to the ground terminal 32 via a bias resistor 34 and is also connected to an output terminal 36 via a capacitor 35. A bias voltage is applied to the base of the oscillating transistor 33 by voltage dividing resistors. 37 and 38 connected between the power terminal 31 and the ground terminal 32. Also, a feedback capacitor 39 is connected between the base and emitter of the oscillating transistor 33 and a feedback capacitor 40 is connected between the emitter of the oscillating transistor 33 and the ground terminal 32.

A resonant circuit 41 includes an inductance element 41a and a varactor diode 41b. One end of the resonant circuit 41 is connected to the base of the oscillating transistor 33 and the other end of the resonant circuit 41 is connected to the ground terminal 32. The cathode of the varactor diode 41b is connected to a control voltage terminal 43 via a choke inductor 42. An external control voltage is applied to the control voltage terminal 43. An oscillation frequency is determined by changing the control voltage.

The circuit shown in FIG. 5 is provided on a circuit board 50 shown in FIG. 6. The circuit board 50 has a multilayered structure. The oscillating transistor 33, the varactor diode 41b, and other circuit components that are not shown, such as the bias resistor 34 and the capacitor 35, are mounted on the upper surface of the circuit board 50. The inductance element 41a (not shown) is formed of a strip line provided on an inner layer of the circuit board 50. The power terminal 31, a plurality of ground terminals 32, the output terminal 36, and the control voltage terminal 43 are provided on end faces of the circuit board 50: A metal cover 51 for covering the circuit has a plurality of downward-protruding lugs 51a, and the lugs 51a are connected to the corresponding ground terminals 32 provided on the end faces of the circuit board 50.

The oscillation frequency of a voltage-controlled oscillator of this type is determined in accordance with the specifications of a transmitting and receiving circuit in which it is used. Thus, for example, for different types of portable telephones, an appropriate oscillation frequency of the voltage-controlled oscillator is needed for each type of portable telephone. Thus, manufacturers must produce many types of voltage-controlled oscillators. This complicates manufacturing process, thus preventing cost reduction.

### SUMMARY OF THE INVENTION

Embodiments of the present invention provide a signal generator capable of varying the frequency of an output signal over a wide range and usable in many types of high-frequency apparatus.

A signal generator according to the present invention includes a voltage controlled oscillation circuit; frequency divider circuits for frequency-dividing an oscillation signal output from the voltage controlled oscillation circuit; a control voltage input terminal for inputting an external control voltage for determining the frequency of the oscillation signal; and frequency divided signal output terminals for outputting frequency divided signals output from the corresponding frequency divider circuits. Thus, a frequency divided signal with a wide frequency range, that is lower than or equal to the frequency of the source oscillation signal of the voltage controlled oscillation circuit, can be output.

The voltage controlled oscillation circuit and the frequency divider circuits may be arranged in the same integrated circuit. The integrated circuit may be provided with the control voltage input terminal and the frequency divided signal output terminals. Thus, the integrated circuit can be used as a frequency synthesizer or the like, and a signal with a desired frequency can be easily output.

The signal generator may further include a circuit board on which the voltage controlled oscillation circuit and the frequency divider circuits are provided. The control voltage input terminal and the frequency division signal output terminals may be provided on end faces or the underside of the circuit board. Thus, a modularized signal generator can be easily formed using existing components.

A plurality of frequency divider circuits may be connected in series and the frequency division signals from the corresponding frequency divide circuits may be output. Thus, the frequency range of a frequency-divided signal can be extended.

Each of the frequency divider circuits may be a variable frequency divider circuit capable of switching a frequency division ratio. Frequency division ratio switching terminals each externally inputting a switching signal for switching the frequency division ratio of the variable frequency divider circuit may be provided. Thus, a frequency-divided signal with a desired frequency can be obtained by external control.

### BRIEF DESCRIPTION OF THE DRAWINGS

FIG. 1 is a block diagram of the structure of a signal generator according to a first embodiment of the present invention;

FIG. 2 is a circuit diagram of a signal generator according to a first embodiment of the present invention;

FIG. 3 is a circuit diagram of a modularized signal generator according to a second embodiment of the present invention;

FIG. 4 is an exploded perspective view of the modularized signal generator according to a second embodiment of the present invention;

FIG. 5 is a circuit diagram of a known signal generator; and

FIG. 6 is an exploded perspective view of the known signal generator.

### DESCRIPTION OF THE PREFERRED EMBODIMENTS

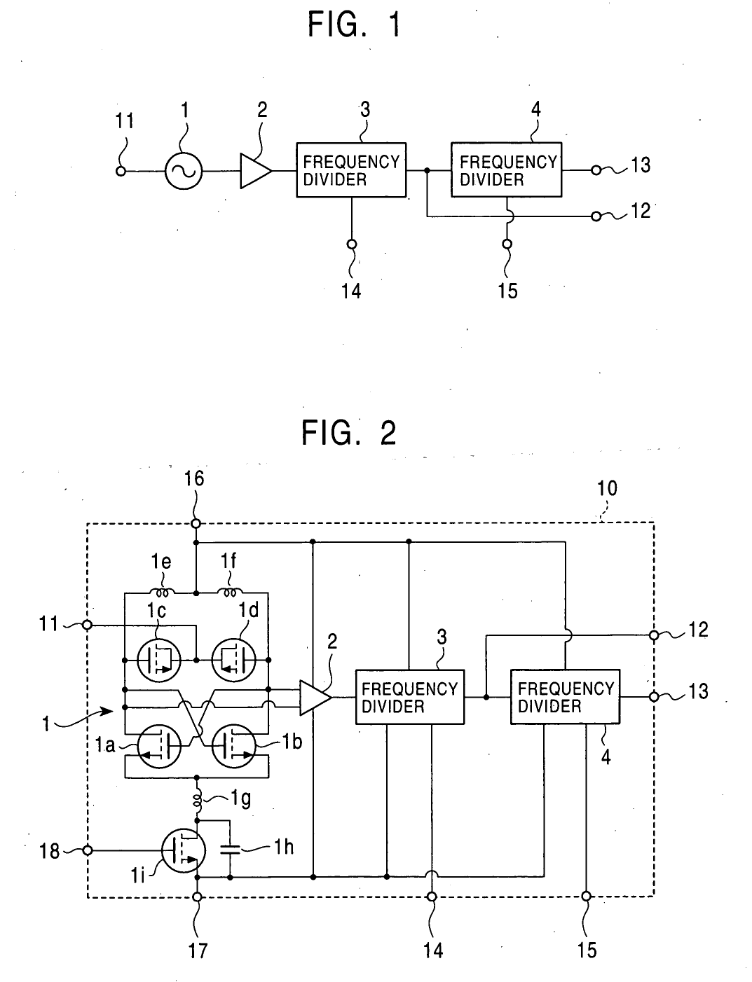

FIG. 1 is a block diagram of a signal generator according to a first embodiment of the present invention. A control voltage for determining an oscillating frequency is applied from a control voltage input terminal 11 to a voltage controlled oscillation circuit 1. A buffer amplifier 2 is provided following the voltage controlled oscillation circuit 1, and a plurality of frequency divider circuits (frequency divider circuits 3 and 4 in this embodiment) may be cascaded to the buffer amplifier 2. Output terminals of the frequency divider circuits 3 and 4 are connected to frequency divided signal output terminals 12 and 13, respectively. Each of the frequency divider circuits 3 and 4 is a variable frequency divider circuit capable of switching a frequency division ratio. Frequency division ratio switching signals are input from frequency division ratio switching terminals 14 and 15 to the frequency divider circuits 3 and 4, respectively. A frequency division ratio determined by the frequency division ratio switching signal may be a frequency division ratio represented by a fraction, as well as a frequency division ratio represented by a whole number.

With the structure described above, each of the frequency divider circuits 3 and 4 switches the frequency division ratio by means of the frequency division ratio switching signal. Thus, a frequency divided signal with a wide frequency range, which is lower than or equal to the frequency of a source oscillation signal of the voltage controlled oscillation circuit 1, can be output.

FIG. 2 shows the signal generator according to the first embodiment as a CMOS integrated circuit. In FIG. 2, only the voltage controlled oscillation circuit 1 is specifically shown. An integrated circuit 10 is provided with the control voltage input terminal 11, the frequency divided signal output terminals 12 and 13, and the frequency division ratio switching terminals 14 and 15. Also, the integrated circuit 10 is provided with a power terminal 16, a ground terminal 17, a bias terminal 18, and the like. A power supply voltage is applied from the power terminal 16 to the voltage controlled oscillation circuit 1, the buffer amplifier 2, and the frequency divider circuits 3 and 4, and a current flows from each of the circuits into the ground terminal 17.

The voltage controlled oscillation circuit 1 is a balanced circuit. The gates of two oscillating field effect transistors (FETs), FET 1a and FET 1b, are connected to the drains of the FET 1b and the FET 1a, respectively. Two FETs, FET 1c and FET 1d, functioning as variable capacitance elements, are connected in series. The drain and source of the FET 1c are connected to the drain and source of the FET 1d. The gate of the FET 1c is connected to the drain of the FET 1a, and the gate of the FET 1d is connected to the drain of the FET 1b. Also, the drain and source of each of the FET 1c and the FET 1d are connected to the control voltage input terminal 11.

Inductors 1e and 1f connected in series in a planar structure are connected in parallel with the FET 1c and the FET 1d, and the node between the inductors 1e and 1f is connected to the power terminal 16. Also, the sources of the FET 1a and FET 1b are connected to the drain of a bias FET 1i via an inductor 1g formed in a planar structure. The source of the FET 1i is connected to the ground terminal 17, and the gate of the FET 1i is connected to the bias terminal 18. Also, the inductor 1g is connected to the ground terminal 17 via a capacitance element 1h. Thus, a bias current is applied from the FET 1i to the FET 1a and FET 1b for oscillation, and the inductor 1g and the capacitance element 1h constitute a filter.

Balanced oscillation signals output from the drains of the FET 1a and the FET 1b are input to the buffer amplifier 2.

Since the signal generator according to the first embodiment is formed by the integrated circuit 10, as shown in FIG. 2, the integrated circuit 10 can be used as a frequency synthesizer or the like, and a signal with a desired frequency can be easily output by determining the frequency division ratio switching signal.

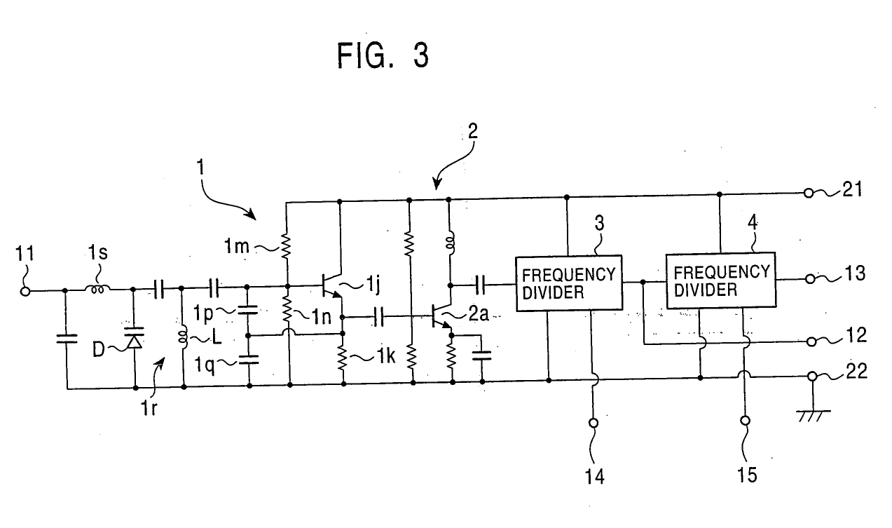

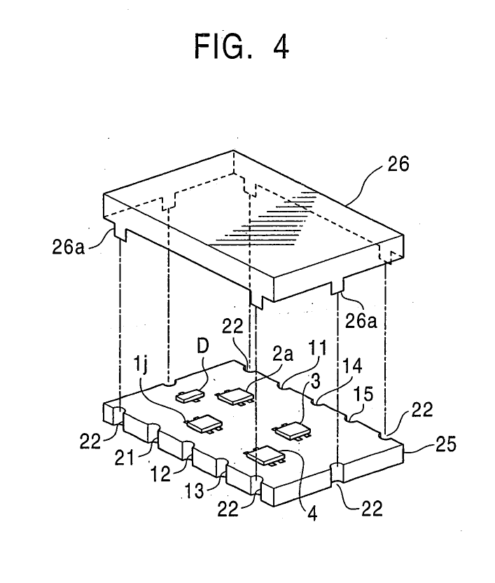

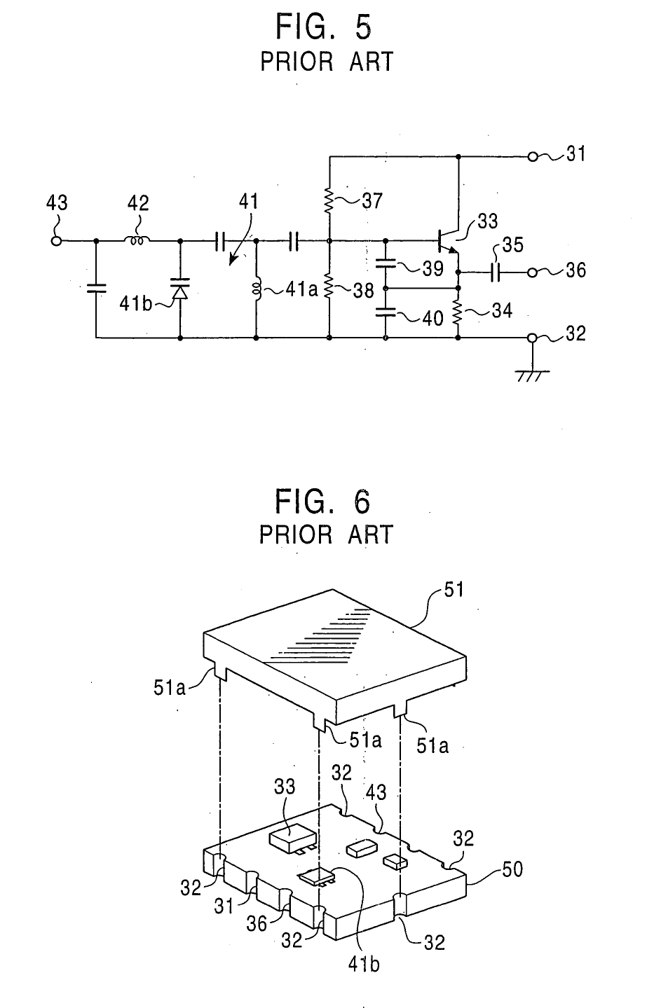

FIG. 3 shows a circuit diagram of a signal generator according to a second embodiment of the present invention in which the voltage controlled oscillation circuit 1, the buffer amplifier 2, and the frequency divider circuits 3 and 4 are provided on a circuit board, forming the signal generator in a modular structure. FIG. 4 is an exploded perspective view of the signal generator in the modular structure.

Referring to FIG. 3, an external power supply voltage is applied between a power terminal 21 and a ground terminal 22. The collector of an oscillating transistor 1j of the voltage controlled oscillation circuit 1 is connected to the power terminal 21, and the emitter of the oscillating transistor 1j is connected to the ground terminal 22 via a bias resistor 1k. A bias voltage is applied to the base of the oscillating transistor 1j by voltage dividing resistors lm and 1n connected between the power terminal 21 and the ground terminal 22. Also, a feedback capacitor 1p is connected between the base and emitter of the oscillating transistor 1j and a feedback capacitor 1q is connected between the emitter of the oscillating transistor 1j and the ground terminal 22.

A resonant circuit 1r includes an inductance element L and a varactor diode D. One end of the resonant circuit 1r is coupled to the base of the oscillating transistor 1j, and the other end of the resonant circuit 1r is connected to the ground terminal 22. The cathode of the varactor diode D is connected to the control voltage input terminal 11 via a choke inductor 1s. An external control voltage is applied to the control voltage input terminal 11. An oscillation frequency is determined by changing the control voltage.

The buffer amplifier 2 coupled to the voltage controlled oscillation circuit 1 includes a common-emitter amplifying transistor 2a, and an oscillation signal amplified by the amplifying transistor 2a is sequentially input to the frequency divider circuits 3 and 4. Each of the frequency divider circuits 3 and 4 is capable of switching the frequency division ratio and is preferably formed as an integrated circuit. Thus, switching signals for switching the frequency division ratio are input from the frequency division ratio switching terminals 14 and 15 to the frequency divider circuits 3 and 4, respectively. Frequency-divided signals are output from the frequency divider circuits 3 and 4 to the frequency divided signal output terminals 12 and 13, respectively.

The circuit shown in FIG. 3 is provided on a circuit board 25 shown in FIG. 4. The circuit board 25 has a multilayered structure. The oscillating transistor 1j, the varactor diode D, the amplifying transistor 2a, the frequency divider circuits 3 and 4, and other circuit components are mounted on the upper surface of the circuit board 25. The inductance element L (not shown) is formed of a strip line provided on an inner layer of the circuit board 25. The control voltage input terminal 11, the power terminal 21, a plurality of ground terminals 22, the frequency divided signal output terminals 12 and 13, and the frequency division ratio switching terminals 14 and 15 are provided on end faces of the circuit board 25. A metal cover 26 for covering the circuit has a plurality of downward-protruding lugs 26a, and the lugs 26a are connected to the corresponding ground terminals 22 provided on the end faces of the circuit board 25.

Each of the terminals may be provided on the underside of the circuit board 25.

With the structure of the second embodiment shown in FIGS. 3 and 4, a modularized signal generator can be easily formed using existing components. Also, a frequency divided signal with a wide frequency range, that is lower than or equal to the frequency of a source oscillation signal, of the voltage controlled oscillation circuit 1, can be output.

What is claimed is:

1. A signal generator, comprising:
a voltage controlled oscillation circuit;
a control voltage input terminal for inputting an external control voltage for determining a frequency of an oscillation signal;
a frequency divider circuit for frequency-dividing an oscillation signal output from the voltage controlled oscillation circuit; and
a frequency divided signal output terminal for outputting a frequency divided signal output from the frequency divider circuit.

2. The signal generator according to claim 1, further comprising a buffer amplifier which couples the oscillation signal output of the voltage controlled oscillator circuit to an input of the frequency divider circuit.

3. The signal-generator according to claim 2, wherein the buffer amplifier has a balanced input and an unbalanced output.

4. The signal generator according to claim 2, wherein the buffer amplifier is a common emitter transistor amplifier.

5. The signal generator according to claim 1, wherein the voltage controlled oscillation circuit and the frequency divider circuit are arranged in an integrated circuit, and wherein the integrated circuit is provided with the control voltage input terminal and the frequency division signal output terminal.

6. The signal generator according to claim 5, wherein the frequency of oscillation of the voltage controlled oscillation circuit is controlled by a FET functioning as a voltage controlled variable capacitor.

7. The signal generator according to claim 5, wherein the integrated circuit is formed utilizing CMOS technology.

8. The signal generator according to claim 1, wherein the voltage controlled oscillation circuit employs field effect transistors (FET).

9. The signal generator of claim 6, wherein the voltage controlled oscillation circuit has a balanced output.

10. The signal generator according to claim 1, further comprising a circuit board on which the voltage controlled oscillation circuit and the frequency divider circuit are provided, wherein the control voltage input terminal and the frequency division signal output terminal are provided on end faces or an underside of the circuit board.

11. The signal generator according to claim 1, wherein the voltage controlled oscillator circuit further comprises a varactor diode in a resonant circuit coupled to a base of an oscillating transistor.

12. The signal generator according to claim 11, wherein the frequency of oscillation of the voltage controlled oscillation circuit is controlled by the external voltage applied to the varactor diode.

13. The signal generator unit of claim 1, wherein a frequency division ratio of the frequency divider circuit is controlled by an externally applied switching signal.

14. The signal generator of claim 1, wherein a frequency division ratio of the frequency divided signal output is a whole number.

15. The signal generator of claim 1, wherein a frequency division ratio of the frequency divided signal output is a fractional number.

16. The signal generator of claim 1, further comprising a plurality of frequency divider circuits, one or more of the plurality of frequency divider circuits having a corresponding frequency divided signal output terminal.

17. The signal generator according to claim 16, wherein the frequency divided signal output from at least two of the plutality of frequency divider circuits are available simultaneously.

18. The signal generator according to claim 16, wherein the plurality of frequency divider circuits are connected in series.

19. The signal generator according to claim 16, wherein at least one of the plurality of frequency divider circuits is a variable frequency divider circuit capable of switching a frequency division ratio.

20. The signal generator according to claim 1, wherein the frequency divided signal output has a frequency that is equal to or lower than the frequency of the oscillation signal.

21. A signal generator, comprising:
means for generating an oscillation signal;
means for frequency dividing the oscillation signal; and
means for outputting a frequency divided signal,
wherein a frequency of the oscillation signal is controlled by a first control means and a frequency division ratio of the frequency dividing means is controlled by a second control means.

22. The signal generator according to claim 21, wherein the means for generating the oscillation signal comprises:
means for generating a balanced output oscillation signal;
means for converting the balanced output oscillation signal to an unbalanced output oscillation signal; and
means for inputting the unbalanced output oscillation signal to the means for frequency dividing the oscillation signal.

23. The signal generator according to claim 21, wherein the means for frequency dividing the oscillation signal comprises:
means for cascading the means for frequency dividing,
wherein at least one of the cascaded means for frequency dividing is connected to the outputting means.

24. The signal generator according to claim 21, wherein the first control means is an externally applied control voltage.

25. The signal generator according to claim 21, wherein the second control means is an externally applied switching signal.

26. A method of generating a signal with a wide frequency range, comprising:
generating a voltage controlled oscillation signal output;
frequency dividing the voltage controlled oscillation signal output;
controlling a frequency division ratio of the voltage controlled oscillation signal output; and
outputting a frequency divided signal.

27. The method according to claim 26, generating a voltage controlled oscillation signal output comprising:
generating a balanced output oscillation signal;
converting the balanced output oscillation signal to an unbalanced output oscillation signal;
controlling a frequency of the balanced output oscillation signal.

28. The method according to claim 27, wherein controlling the balanced output oscillation signal comprises applying an external voltage.

29. The method according to claim 26, wherein controlling the frequency division ratio comprises applying an external switching voltage.
